(19) United States
(12) Patent Application Publication
(10) Pub. No.: US 2011/0168439 A1
(43) Pub. Date: Jul. 14, 2011

(54) MULTILAYER CERAMIC CIRCUIT BOARD AND METHOD OF MANUFACTURING THE SAME

(75) Inventors: Myung Whun CHANG, Seoul (KR); Jin Waun Kim, Hwaseong (KR); Dae Hyeong Lee, Seoul (KR); Ki Pyo Hong, Yongin (KR)

(73) Assignee: SAMSUNG ELECTRO-MECHANICS CO., LTD.

(21) Appl. No.: 12/794,118

(22) Filed: Jun. 4, 2010

(30) Foreign Application Priority Data
Jan. 13, 2010 (KR) 10-2010-0003167

(51) Int. Cl. H05K 1/11; B29C 65/02

(52) U.S. Cl. 174/264; 156/89.12

(57) ABSTRACT

There is provided a method of manufacturing a multilayer ceramic circuit board. A multilayer ceramic circuit board according to an aspect of the invention may include: preparing a plurality of ceramic green sheets; forming a recess having a desired line shape and a via hole connected to the recess in at least one of the plurality of ceramic green sheets; forming a conductive via by filling the via hole with a conductive material; forming a circuit line connected to the conductive via by filling the recess with a conductive material; stacking the plurality of ceramic green sheets upon one another to thereby form a ceramic green sheet stack; and sintering the ceramic green sheet stack.

### CROSS-REFERENCE TO RELATED APPLICATIONS

This application claims the priority of Korean Patent Application No. 10-2010-0003167 filed on Jan. 13, 2010, in the Korean Intellectual Property Office, the disclosure of which is incorporated herein by reference.

### BACKGROUND OF THE INVENTION

1. Field of the Invention

The present invention relates to a multilayer ceramic circuit board and a method of manufacturing the same, and more particularly, to a multilayer ceramic circuit board and a method of manufacturing the same that can prevent the occurrence of defects in fine circuit lines.

2. Description of the Related Art

As the growing trend towards a reduction in the size of electronic components has accelerated, small modules and boards have been developed by the precision-manufacturing, micro patterning, and thin-film construction of electronic components.

However, when generally used printed circuit boards (PCBs) are employed in small-sized electronic components, a reduction in the size thereof may be limited, signal loss may occur in the high frequency range, and reliability may be reduced at high-temperatures and in humidity.

In order to overcome the above-described disadvantages, a board made from ceramic has been used instead of a PCB. As for a ceramic board, a low temperature co-fired ceramic (LTCC) board that contains glass components is in widespread use.

This low temperature co-fired ceramic (LTCC) board begins with a process of providing a plurality of ceramic green sheets by using a slurry containing a ceramic composition. After a circuit pattern configuring an interlayer circuit is formed on each of the ceramic green sheets, the ceramic green sheets are then stacked upon one another and fired to thereby manufacture a desired multilayer ceramic circuit board. Here, the interlayer circuit, formed on the plurality of ceramic green sheets, includes conductive vias and circuit lines.

In the related art, in order to form circuit patterns on a plurality of ceramic green sheets, via holes are formed in the individual ceramic green sheets at predetermined positions by laser processing or the like, and the via holes are filled with metallic materials. Through this screen printing process, desired circuit lines can be formed at the same time.

However, a method of forming a circuit pattern according to the related art forms a stepped structure at the interface between ceramic green sheets due to the circuit patterns formed on the individual ceramic green sheets, particularly, circuit lines. When a plurality of ceramic green sheets are stacked upon one another, specific portions may protrude so that they may inhibit the manufacture of a multilayer ceramic circuit board having a uniform thickness.

In particular, a low temperature co-fired ceramic circuit board may be used in a probe card. This ceramic circuit board is manufactured in such a manner that a ceramic board and circuit lines formed of a metallic material are fired simultaneously at a firing temperature of 200° C. to 1,000° C., for example. During co-firing, the circuit lines having a uniform width by coating a conductive paste may shrink so that the circuit lines may be partially disconnected.

A reduction in the board size and an increase in the integration of a board cause a reduction in the width of the circuit lines, which may aggravate these defects.

### SUMMARY OF THE INVENTION

An aspect of the present invention provides a method of manufacturing a multilayer ceramic circuit board that can accurately control a width of a circuit line by processing a recess at a position where the circuit line is formed on a ceramic green sheet.

An aspect of the present invention also provides a multilayer ceramic circuit board being manufactured according to the above manufacturing method.

According to an aspect of the present invention, there is provided a method of manufacturing a multilayer ceramic circuit board, the method including: preparing a plurality of ceramic green sheets; forming a recess having a desired line shape and a via hole connected to the recess in at least one of the plurality of ceramic green sheets; forming a conductive via by filling the via hole with a conductive material; forming a circuit line connected to the conductive via by filling the recess with a conductive material; stacking the plurality of ceramic green sheets upon one another to thereby form a ceramic green sheet stack; and sintering the ceramic green sheet stack.

A top portion of the conductive via may extend as far as the recess adjacent to the via hole.

The top portion of the conductive via, located at the recess, may be inclined towards the recess.

The top portion of the conductive via may at least partially overlap the circuit line.

The forming of the recess may include performing laser beam irradiation on the at least one ceramic green sheet to thereby form the recess having the line shape.

The recess may have a depth 10 to 70% of a thickness of the at least one ceramic green sheet.

The forming of the circuit line may be performed by a screen printing process using a squeegee.

A method of manufacturing according to an aspect of the invention may be used to manufacture a probe circuit board.

According to another aspect of the present invention, there is provided a multilayer ceramic circuit board including: a ceramic stack having a plurality of ceramic sheets; and an interlayer circuit unit having circuit lines and conductive vias provided in the plurality of ceramic sheets, wherein at least one of the circuit lines is formed of a conductive material filling the recess provided in the ceramic sheet, and the at least one circuit line is connected to the conductive via.

A top portion of the conductive via may extend as far as the recess adjacent to the conductive via.

The top portion of the conductive via, located at the recess, may be inclined towards the recess.

The top portion of the conductive via may at least partially overlap the circuit line.

The circuit line may be connected to a conductive via provided in a corresponding ceramic layer having the circuit line therein.

The recess may have a depth 10 to 70% of a thickness of the at least one ceramic green sheet.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1 through 3 are cross-sectional views illustrating the process flow to describe an example of a circuit pattern forming process of a method of manufacturing a multilayer ceramic circuit board according to an exemplary embodiment of the present invention;

FIG. 4 is a schematic enlarged view illustrating a connection portion between a conductive via and a circuit line, shown in FIG. 3;

FIGS. 5A through 5C are cross-sectional views illustrating an example of a method of manufacturing a multilayer ceramic circuit board according to an exemplary embodiment of the present invention; and

FIGS. 6A and 6B are optical microscope photographs showing a cross section of a multilayer ceramic circuit board manufactured according to an exemplary embodiment of the present invention.

### DETAILED DESCRIPTION OF THE PREFERRED EMBODIMENT

Exemplary embodiments of the present invention will now be described in detail with reference to the accompanying drawings.

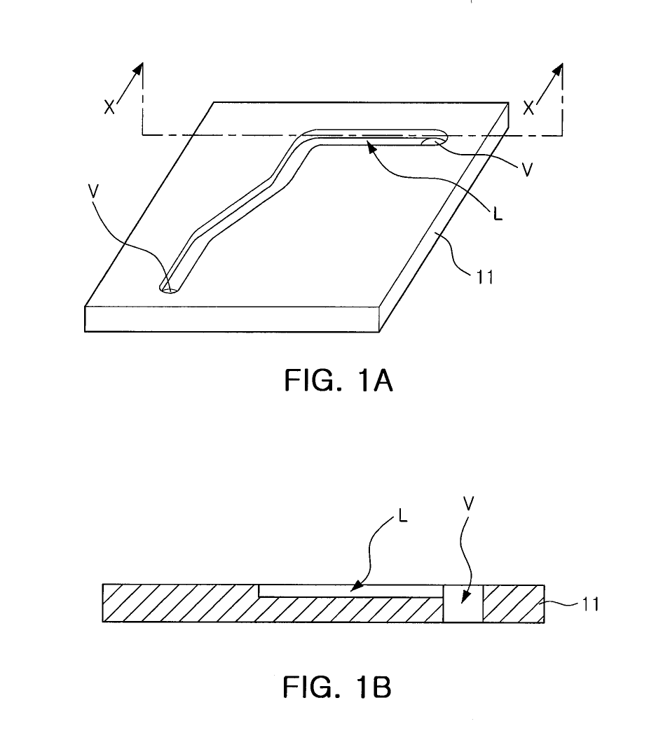

FIGS. 1 through 3 are cross-sectional views illustrating the process flow to describe an example of a process of forming a circuit pattern in a method of manufacturing a multilayer ceramic circuit board according to an exemplary embodiment of the invention.

The process of forming a circuit pattern being performed in this embodiment begins with a process of forming a recess having a line shape in a ceramic green sheet.

As shown in FIG. 1A, a recess L having a desired line shape is formed in a ceramic green sheet 11. The recess L, shown in FIG. 1A, has the line shape corresponding to a desired circuit line. That is, the line width and the position of the circuit line to be formed in the ceramic green sheet 11 are defined by the width and position of the recess L.

In the same manner as imprinting, the process of forming a recess may be performed by applying pressure to form a desired shape. A desired recess may also be formed by performing laser beam irradiation on the ceramic green sheet 11.

In this embodiment, the ceramic green sheet 11 may include via holes V connected to both ends of the recess L. The via holes V are provided in order to form conductive vias, which are structures for interlayer electrical communication, to be connected to a circuit line. The via hole V may be formed by a general punching method.

As shown in FIG. 1B, in this embodiment, the recess L, formed to provide a circuit line, has a predetermined depth in the ceramic green sheet 11.

As such, a desired thickness of the circuit line can be stably obtained by the depth of the recess L, thereby markedly reducing open failures of circuit lines.

The recess L may have a depth 10 to 70% of the thickness of at least one ceramic green sheet 11.

When the recess L has a depth less than 10% of the thickness of the ceramic green sheet 11, it may be difficult to obtain a desired circuit line with a sufficient thickness. When the recess L has a depth greater than 70% of the thickness of the ceramic green sheet 11, defects are likely to occur while the recess L is formed.

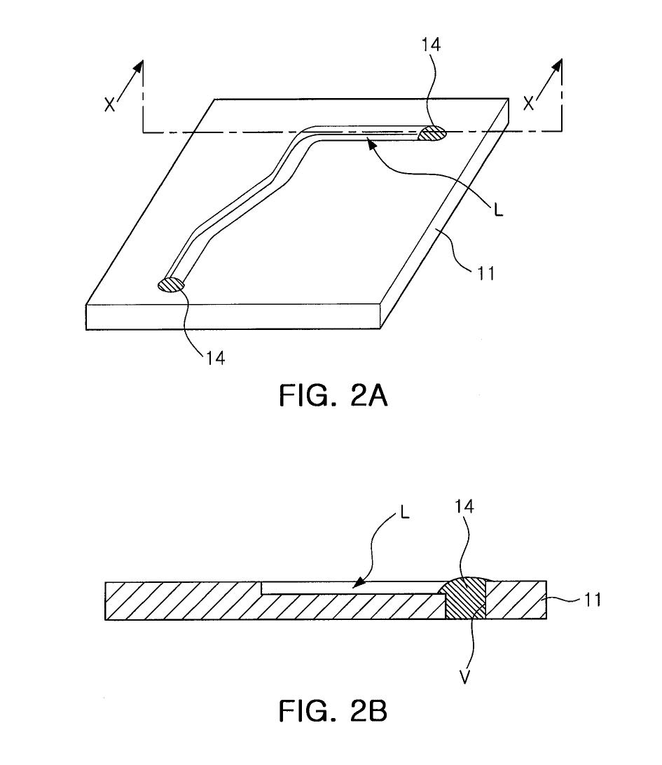

Then, as shown in FIGS. 2A and 2B, the via holes V are filled with a conductive material to thereby form conductive vias 14.

The via holes V are filled with a conductive material before the recess L is filled to form a circuit line. As shown in FIG. 2B, the via holes V may be filled with a conductive material, such as Ag paste. The via holes V may be formed within the recess L, and the conductive material filling the via hole V may be formed to have an upper surface with a gentle slope disposed within the recess L.

Unlike this embodiment, when only a recess L is formed in a corresponding ceramic green sheet 11 in order to provide a circuit line, a process of filling the recess L to provide a circuit line may be performed without filling via holes.

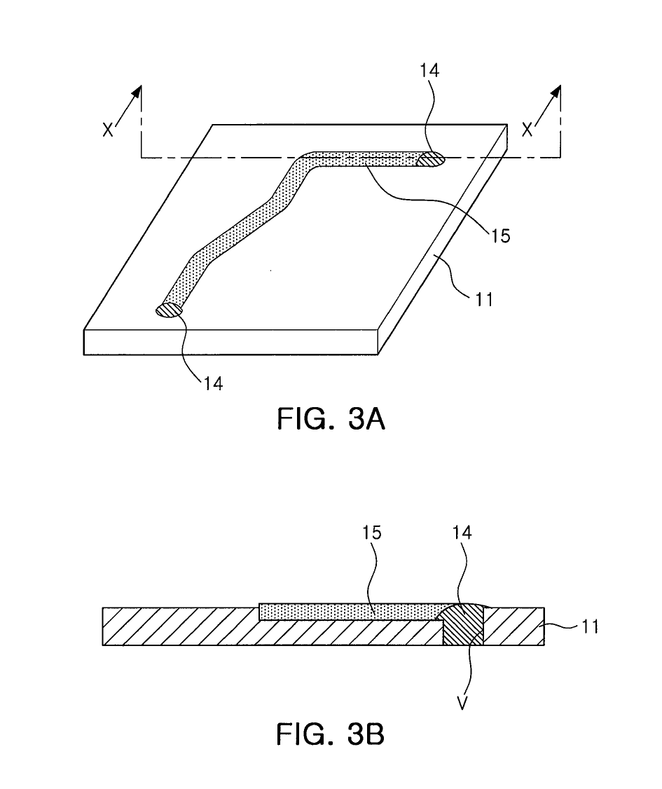

Then, as shown in FIGS. 3A and 3B, the recess L, formed in the ceramic green sheet 11, is filled with a conductive material to thereby form the circuit line 15.

In this embodiment, a circuit line may be formed by screen printing.

When a screen mesh is pressurized against the upper surface of the ceramic green sheet by using a squeegee, even though a screen makes tight contact with the upper surface of the screen ceramic green sheet 11, the recess L ensures a gap (that is, a depth of the recess) allowing for the thickness of the circuit line 15, thereby more finely forming the circuit line 15 with a desired thickness.

The position at which the circuit line 15 is formed is accurately defined by the recess, so that the circuit line 15 can be accurately connected to the conductive vias 14 and it is also possible to ensure a stable connection between the circuit line 15 and the via holes.

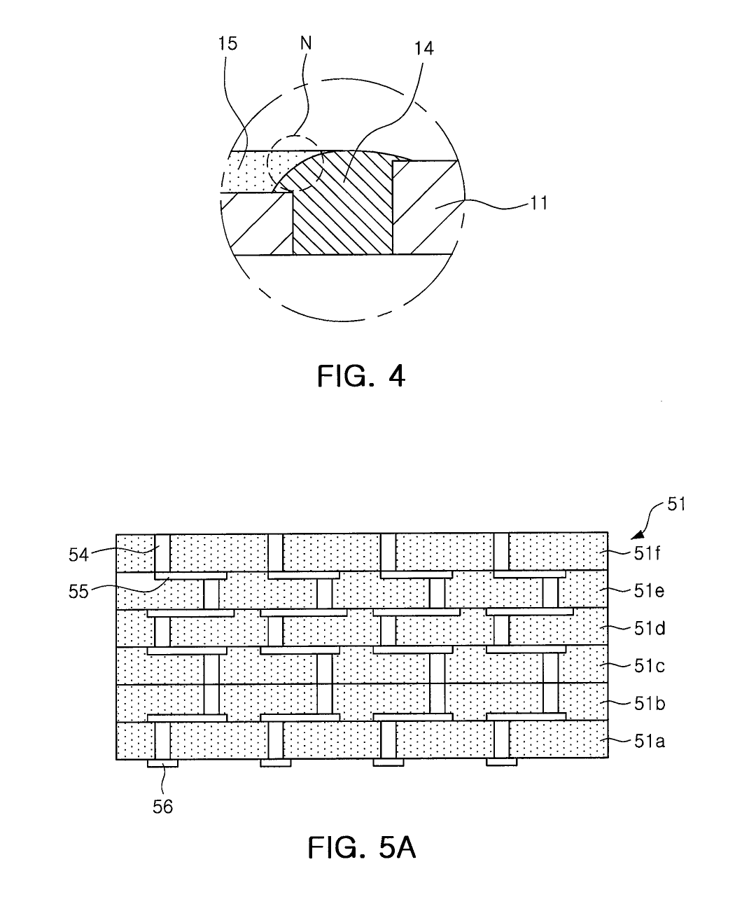

Specifically, in FIG. 4, an upper part of the conductive material filling the via hole V may partially cover the recess L for lines. That is, since a portion of an upper part of the via hole that communicates with the recess is opened, the conductive material filling the via hole may be located at the recess adjacent thereto. The conductive material filling the via hole and being present in the recess adjacent thereto may lead to a stable connection with the via hole and a conductive line to be subsequently formed.

In light of these facts, as shown in FIG. 4, the upper part of the conductive via, which is located at the recess, may be inclined towards the recess, and may partially overlap the circuit line to be subsequently formed. As such, a stepped portion of the upper part of the conductive via 14 becomes a gentle slope, thereby ensuring a stable connection.

At least one of a plurality of ceramic green sheets for a multilayer ceramic circuit board according to an exemplary embodiment of the invention may use the ceramic green sheet 11 being manufactured according to the above-described embodiment of the invention.

A method of manufacturing a multilayer ceramic circuit board using the above-described ceramic green sheet according to another exemplary embodiment of the invention is provided. A multilayer ceramic circuit board, which is exemplified in this embodiment, can be applied to a board for a probe card having a complicated interlayer circuit as well as a circuit board for various types of electronic device modules.

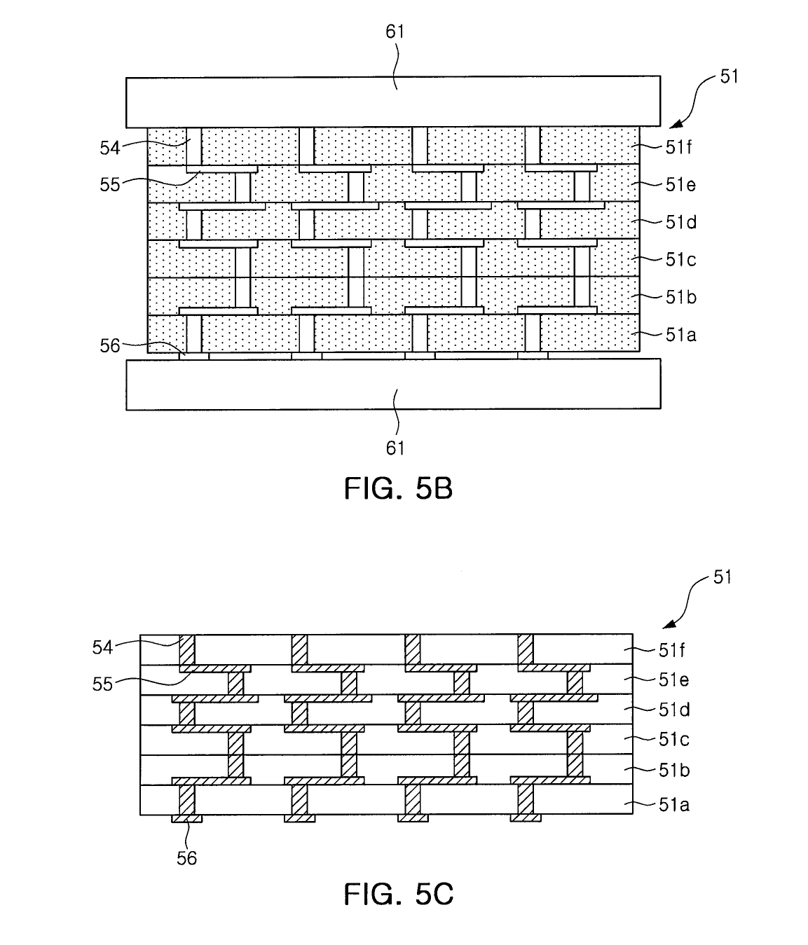

An example of a method of manufacturing a multilayer ceramic circuit board according to an exemplary embodiment of the invention will be described with reference to cross-sectional views illustrating the process flow shown in FIGS. 5A through 5C.

Referring to FIG. 5A, a plurality of ceramic green sheets 51a to 51f are stacked to thereby prepare a ceramic green sheet stack 51. Each of the ceramic green sheets 51a to 51f has circuit lines 55 and conductive vias 54 that form an interlayer circuit.

As the ceramic green sheets 51a to 51f, ceramic green sheets being manufactured according to the method of manufacturing a ceramic green sheet, described in FIGS. 1 to 3, may be used. That is, the circuit lines 55, formed on the ceramic green sheets 51a to 51f, respectively, have recesses being filled with a conductive material. Depending on a configuration of a desired circuit board, a pattern 56 may be formed for an external terminal on the bottom surface of the ceramic green sheets 51a to 51f.

Then, the ceramic green sheet stack 51 is sintered. Here, the ceramic green sheet stack 51 may be sintered by a non-shrinkage process. Specifically, hard-to-sinter constraining layers are disposed on upper and lower surfaces of the ceramic green sheet stack 51 to thereby inhibit shrinkage in a horizontal direction, so that the ceramic green sheet stack 51, shown in FIG. 5C, is obtained.

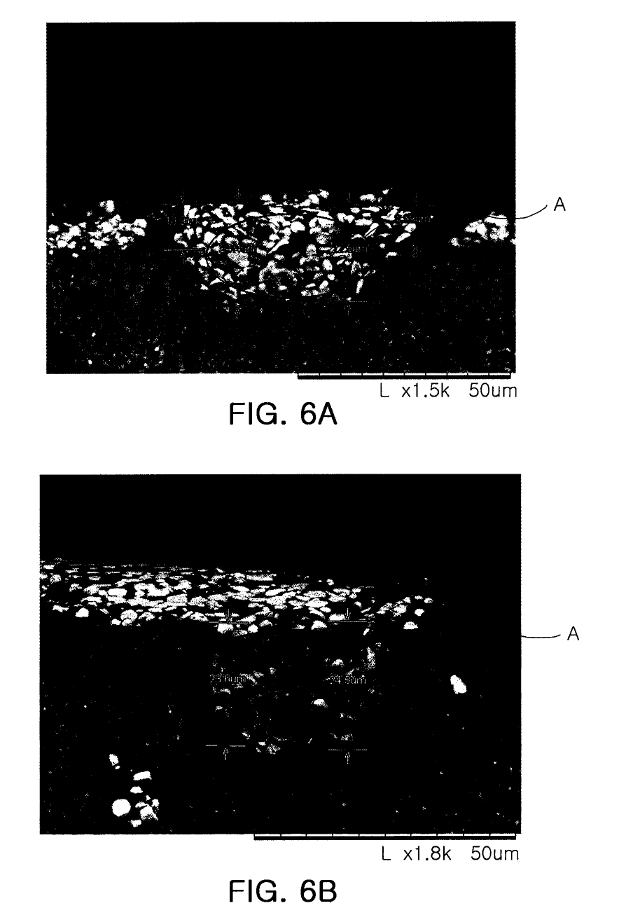

The multilayer ceramic circuit board according to this embodiment can prevent a partial reduction in the width of a circuit line during a sintering process and stably realizes a line width of the circuit line. FIGS. 6A and 6B show an example in which a fine circuit line is formed. As an example, a fine circuit line having a width of 50 μm is formed in such a manner that a recess having a depth of approximately 25 μm is provided and the recess with a conductive material is filled. As such, a circuit line having a fine width (less than 100 μm) can be accurately controlled by using a recess, and a position at which the circuit line is formed can be accurately controlled.

Furthermore, an open failure caused by incomplete line printing due to a stepped portion of the via filled with a conductive material at a so-called “neck” portion, at which a conductive line and a via are connected, can be effectively prevented by disposing conductive via holes at positions at which a recess is formed.

As set forth above, according to exemplary embodiments of the invention, open failures caused by a partial reduction in the width of a circuit line being printed during sintering can be effectively prevented. Also, it is possible to accurately control a width of a circuit line to be provided on a multilayer ceramic circuit board when the circuit line has a fine width of less than 100 μm, and a thickness of a circuit line can also be ensured using a depth of a recess in a screen printing process in which a squeegee comes into contact with an upper surface of a ceramic green sheet.

In particular, an open failure caused by incomplete line printing due to a stepped portion of the via filled with a conductive material at a so-called “neck” portion, at which a conductive line and a via are connected, can be effectively prevented.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a multilayer ceramic circuit board, the method comprising:
preparing a plurality of ceramic green sheets;
forming a recess having a desired line shape and a via hole connected to the recess in at least one of the plurality of ceramic green sheets;
forming a conductive via by filling the via hole with a conductive material;
forming a circuit line connected to the conductive via by filling the recess with a conductive material;
stacking the plurality of ceramic green sheets upon one another to thereby form a ceramic green sheet stack; and
sintering the ceramic green sheet stack.

2. The method of claim 1, wherein a top portion of the conductive via extends as far as the recess adjacent to the via hole.

3. The method of claim 2, wherein the top portion of the conductive via, located at the recess, is inclined towards the recess.

4. The method of claim 3, wherein the top portion of the conductive via at least partially overlaps the circuit line.

5. The method of claim 1, wherein the forming of the recess comprises performing laser beam irradiation on the at least one ceramic green sheet to thereby form the recess having the line shape.

6. The method of claim 1, wherein the recess has a depth 10 to 70% of a thickness of the at least one ceramic green sheet.

7. The method of claim 1, wherein the forming of the circuit line is performed by a screen printing process using a squeegee.

8. A multilayer ceramic circuit board manufactured by the method of claim 1.

9. A probe card comprising a multilayer ceramic circuit board manufactured by the method of claim 8.

10. A multilayer ceramic circuit board comprising:
a ceramic stack having a plurality of ceramic sheets; and
an interlayer circuit unit having circuit lines and conductive vias provided in the plurality of ceramic sheets,
wherein at least one of the circuit lines is formed of a conductive material filling the recess provided in the ceramic sheet, and the at least one circuit line is connected to the conductive via.

11. The multilayer ceramic circuit board of claim 10, wherein a top portion of the conductive via extends as far as the recess adjacent to the conductive via.

12. The multilayer ceramic circuit board of claim 11, wherein the top portion of the conductive via, located at the recess, is inclined towards the recess.

13. The multilayer ceramic circuit board of claim 12, wherein the top portion of the conductive via at least partially overlaps the circuit line.

14. The multilayer ceramic circuit board of claim 10, wherein the recess has a depth 10 to 70% of a thickness of the at least one ceramic green sheet.

15. A probe card comprising the multilayer ceramic circuit board of claim 10.
